(19) United States
(12) Patent Application Publication
(10) Pub. No.: US 2026/0227438 A1
(43) Pub. Date: Aug. 6, 2026

(54) METHODS, SYSTEMS, AND COMPUTER READABLE MEDIA FOR PROCESSING TIME ERROR DATA USING UNSUPERVISED MACHINE LEARNING

(71) Applicant: Keysight Technologies, Inc., Santa Rosa, CA (US)

(72) Inventors: Jaydeep Das, Kolkata (IN); Suman Mishra, Kolkata (IN); Chinmay Mahata, Kolkata (IN)

(21) Appl. No.: 19/576,048

(22) Filed: Mar. 24, 2026

(51) Int. Cl. G01R 31/317; G06F 18/23213; G06N 20/00

(52) U.S. Cl. CPC G01R 31/31726; G06F 18/23213; G06N 20/00

(57) ABSTRACT

A method for obtaining time error measurements and processing the time error measurements using unsupervised machine learning includes generating, using a time error measurement tool, timing synchronization test traffic and transmitting the timing synchronization test traffic to a device under test. The method further includes receiving, by the time error measurement tool, responsive timing synchronization test traffic from the device under test. The method further includes generating, by the time error measurement tool, measurements of time error between a clock in the device under test and a reference clock. The method further includes feeding the measurements of time error to a machine learning model that utilizes unsupervised learning to cluster the time error measurements. The method further includes receiving, as output from the machine learning model, clusters of the time error measurements for a plurality of different time durations.

### TECHNICAL FIELD

The subject matter described herein relates to analyzing time error data in time sensitive networks. More particularly, the subject matter described herein relates to methods, systems, and computer readable media for processing time error data using unsupervised machine learning.

### BACKGROUND

In time sensitive networks, it is of utmost importance for a device to synchronize itself with respect to a clock source. The inability of network devices to perform time synchronization can result in non-deterministic behavior being injected into a network. Such erroneous behavior is not acceptable in time sensitive networks, where real-time coordination among multiple network-connected systems is desired. A time sensitive networks time error measurement tool needs to test clock devices to check how accurately the clock devices can synchronize with respect to a reference clock.

In a bid to synchronize itself with an external reference source, a clock introduces some errors. These are called time errors. More specifically, time error is the difference of the time T(t) generated by the clock under test from time T_{ref}(t) generated by a reference clock. Mathematically, time error=T_{ref}(t)−T(t).

Formally, time error (TE) can be defined as the difference between time T(t) generated by the clock under observation and time T_{ref}(t) generated by a reference clock. Denoted as x(t) at a certain instant of time t.

$$X ( t ) = T ( t ) - {T}_{ref} ( t )$$

Conventional time error measurement tools obtain instantaneous time error measurements. However, raw instantaneous time error measurements are difficult to interpret and require expert analysis to determine causes of time errors, types of time errors, trends in time errors, an anomalies in time errors. Accordingly, in light of these and other difficulties, there exists a need for improved methods, systems, and computer readable media for obtaining and processing time error measurements of a device under test to facilitate subsequent analysis of the time error measurements.

### SUMMARY

A method for obtaining time error measurements and processing the time error measurements using unsupervised machine learning includes generating, using a time error measurement tool, timing synchronization test traffic and transmitting the timing synchronization test traffic to a device under test. The method further includes receiving, by the time error measurement tool, responsive timing synchronization test traffic from the device under test. The method further includes generating, by the time error measurement tool, measurements of time error between a clock in the device under test and a reference clock. The method further includes feeding the measurements of time error to a machine learning model that utilizes unsupervised learning to cluster the time error measurements. The method further includes receiving, as output from the machine learning model, clusters of the time error measurements for a plurality of different time durations.

According to another aspect of the subject matter described herein, the machine learning model utilizes self-organizing maps to generate the clusters.

According to another aspect of the subject matter described herein, the machine learning model utilizes k-means clustering to generate the clusters.

According to another aspect of the subject matter described herein, generating the time synchronization test traffic includes generating the time synchronization test traffic that includes impairments to simulate different causes of time errors.

According to another aspect of the subject matter described herein, generating the time synchronization test traffic that includes impairments to simulate the different causes of the time errors includes generating the time synchronization test traffic with impairments that simulate power supply instability, network congestion, and temperature variations. According to another aspect of the subject matter described herein, the method includes identifying, from the clusters, causes of the time errors.

According to another aspect of the subject matter described herein, the method includes providing a dashboard interface for allowing a user to view the clusters.

According to another aspect of the subject matter described herein, the clusters include clusters of arithmetic means of the time error measurements.

According to another aspect of the subject matter described herein, the clusters include barycenter averages of the time error measurements.

According to another aspect of the subject matter described herein, a system for obtaining time error measurements and processing the time error measurements using unsupervised machine learning is provided. The system includes a time error measurement tool including at least one processor and a memory for generating timing synchronization test traffic, transmitting the timing synchronization test traffic to a device under test, receiving responsive timing synchronization test traffic from the device under test, and generating measurements of time error between a clock in the device under test and a reference clock. The system further includes a machine learning model implemented by the at least one processor for receiving, as inputs, the time error measurements generated by the time error measurement tool and utilizing unsupervised learning to generate, as outputs, clusters of the time error measurements for a plurality of different time durations.

According to another aspect of the subject matter described herein, the machine learning model is configured to utilize self-organizing maps to generate the clusters.

According to another aspect of the subject matter described herein, the machine learning model is configured to utilize k-means clustering to generate the clusters.

According to another aspect of the subject matter described herein, the system includes a cluster analysis module for identifying, from the clusters, causes of the time errors.

According to another aspect of the subject matter described herein, the time synchronization test traffic includes impairments to simulate different causes of time errors.

According to another aspect of the subject matter described herein, the impairments simulate power supply instability, network congestion, and temperature variations.

According to another aspect of the subject matter described herein, the system includes a dashboard interface for allowing a user to view the clusters.

According to another aspect of the subject matter described herein, the machine learning model is configured to output clusters of arithmetic means of the time errors.

According to another aspect of the subject matter described herein, the machine learning model is configured to output barycenter averages of the time error measurements.

According to another aspect of the subject matter described herein, a non-transitory computer readable medium having stored thereon executable instructions that when executed by a processor of a computer control the computer to perform steps is provided. The steps include generating, using a time error measurement tool, timing synchronization test traffic and transmitting the timing synchronization test traffic to a device under test. The steps further include receiving, by the time error measurement tool, responsive timing synchronization test traffic from the device under test. The steps further include generating, by the time error measurement tool, measurements of time error between a clock in the device under test and a reference clock. The steps further include feeding the measurements of time error to a machine learning model that utilizes unsupervised learning to cluster the time error measurements. The steps further include receiving, as output from the machine learning model, clusters of the time error measurements for a plurality of different time durations.

The subject matter described herein can be implemented in software in combination with hardware and/or firmware. For example, the subject matter described herein can be implemented in software executed by a processor. In one exemplary implementation, the subject matter described herein can be implemented using a non-transitory computer readable medium having stored thereon computer executable instructions that when executed by the processor of a computer control the computer to perform steps. Exemplary computer readable media suitable for implementing the subject matter described herein include non-transitory computer-readable media, such as disk memory devices, chip memory devices, programmable logic devices, and application specific integrated circuits. In addition, a computer readable medium that implements the subject matter described herein may be located on a single device or computing platform or may be distributed across multiple devices or computing platforms.

### BRIEF DESCRIPTION OF THE DRAWINGS

Preferred embodiments of the subject matter described herein will now be explained with reference to the accompanying drawings, wherein like reference numerals represent like parts, of which:

FIG. 1 is a diagram of a time error measurement tool for testing a PTP device and using an ML model to generate clusters from time error measurements made by the time error measurement tool;

FIG. 2 is a message flow diagram illustrating exemplary messages exchanged between a time error measurement tool and a PTP DUT in collecting and feeding time error measurements to an ML model that clusters the time error measurements;

FIG. 3 is a flow chart illustrating an exemplary process for obtaining and clustering time error measurements;

FIG. 4 illustrates an example of clustering using self-organizing maps.

FIG. 5 illustrates and example of clustering using k-means clustering;

FIG. 6 illustrates an example of some input data series of time error measurements for different time intervals and in different physical conditions that may be provided as input to the ML model;

FIG. 7 illustrates an example of clusters of time error data identified by a machine learning model when the machine learning model is configured to utilize self-organizing maps to generate the clusters;

FIG. 8 is a histogram of the clusters of average time error values identified when the machine learning model utilizes self-organizing maps and the time series data used to generate the histogram;

FIG. 9 illustrates clusters of time error values identified by the machine learning model for the input time series illustrates in FIG. 6 where the machine learning model utilizes k-means clustering to identify the clusters;

FIG. 10 is a histogram of the clusters of time error measurements identified by machine learning model using k-means clustering;

FIG. 11 illustrates clusters with reduced dimensions identified by machine learning model using k-means clustering;

FIG. 12 is a histogram of clusters of time error measurements identified using k-means clustering and the time series data used to generate the histograms; and

FIG. 13 is a diagram illustrating an example of a dashboard interface for allowing a user to view clusters.

### DETAILED DESCRIPTION

### Measuring Time errors

The Generic Precision Time Protocol (gPTP) employs a set of timestamped messages—sync, follow up, peer delay request, peer delay response, and peer delay follow up—to measure time discrepancies between time-aware devices. These messages enable devices to calculate clock error relative to their peers.

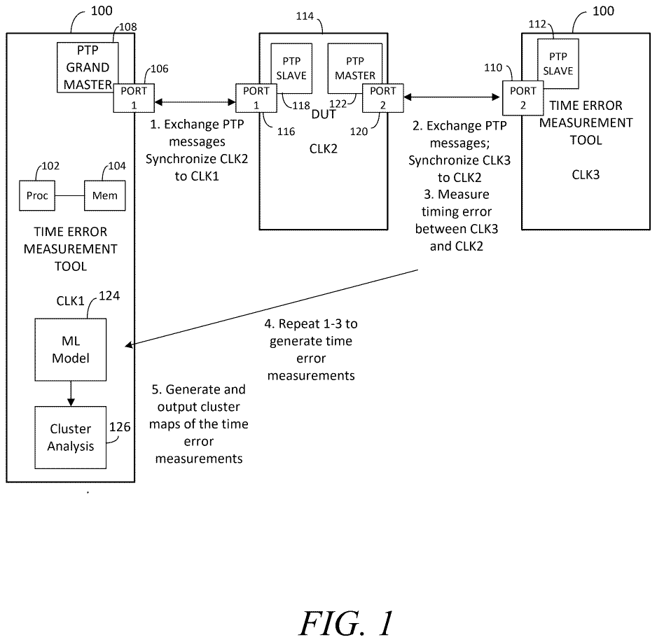

FIG. 1 is a diagram of a time error measurement tool for testing a PTP device and using an ML model to generate clusters from time error measurements made by the time error measurement tool. Referring to FIG. 1, a time error measurement tool 100 includes at least one processor 102 and memory 104. Time error measurement tool 100 includes a first port 106 on which a PTP grand master 108 is implemented. Time error measurement tool 100 includes a second port 110 on which a PTP slave 112 is implemented. A device under test (DUT) 114 includes a first port 116 on which a PTP slave 118 is implemented and a second port 120 on which a PTP master 122 is implemented. Time error measurement tool 100 further includes an ML model 124 that receives the time error measurements as input, clusters the time error measurements using unsupervised machine learning, and generates as output, clusters of the time error measurements. Time error measurement tool further includes a cluster analysis module 126 that analyzes the clusters of time error measurements to identify anomalies in the time error measurements, causes of the time errors, trends in the time error measurements, and types of time errors. For the sample time error set, we collected error samples using simulated or emulated impairments that simulate real world physical conditions, including temperature variations, electromagnetic interference, power supply instability, network congestion, along with normal/standard conditions. That is, the timing synchronization traffic generated by time error measurement tool 100 includes timing synchronization traffic with impairments that emulate these and other real-world conditions, as well as timing synchronization traffic without impairments.

Referring to the message flow illustrated in FIG. 1, in step 1, PTP grand master 108 of time error measurement tool 100 exchanges PTP timing synchronization messages with PTP slave 118 of DUT 114 to synchronize clock CLK2 of DUT 114 with clock CLK1 of time error measurement tool 100. In step 2, PTP master 122 of PTP DUT 114 exchanges PTP timing synchronization messages with PTP slave 112 of time error measurement tool 100 to synchronize CKL3 of time error measurement tool 100 with CLK2 of PTP DUT 114. In step 3, time error measurement tool 100 measures the time error on port 2 110. In step 4, time error measurement tool 100 repeats steps 1-3 to generate a plurality of time error measurements. In step 4, time error measurement tool 100 feeds the time error measurements to an ML model 124 implemented by time error measurement tool 500. In step 5, ML model 124 generates and outputs clusters of the time error measurements for different time durations.

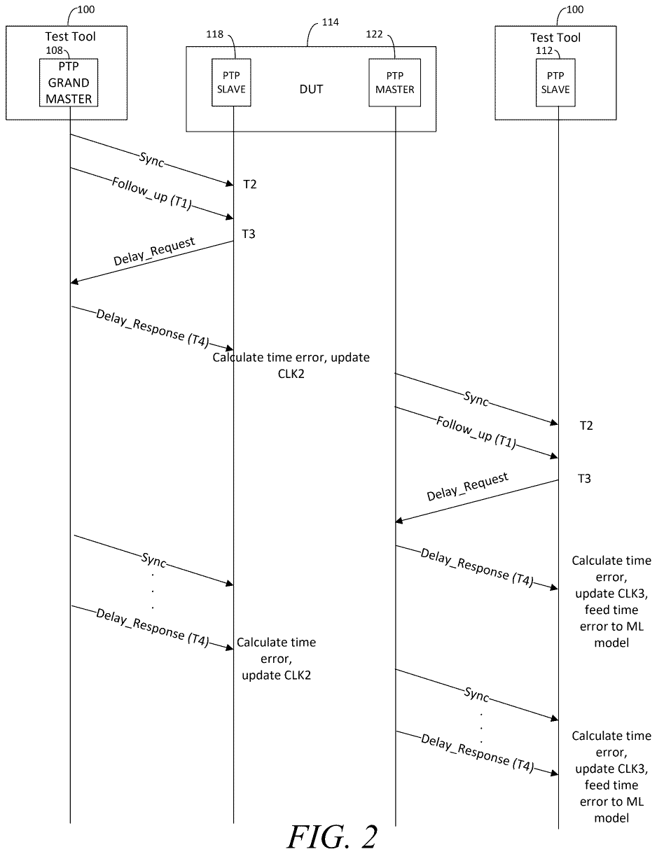

FIG. 2 is a message flow diagram illustrating exemplary messages exchanged between time error measurement tool 100 and PTP DUT 114 in collecting and feeding time error measurements to ML model 124. Referring to FIG. 2, PTP grand master 108 of time error measurement tool 100 sends a sync message to PTP slave 118 implemented by DUT 114. PTP slave 118 of DUT 114 records the time T2 of receipt of the sync message. PTP grand master 108 of time error measurement tool 100 sends a follow up message carrying the value T1 to PTP slave 118 of DUT 114. The time value T1 is the time at which PTP grand master 108 of time error measurement tool 100 transmits the sync message. At time T3, PTP slave 118 of DUT 114 sends a delay request message to PTP grand master 108 of time error measurement tool 100. PTP grand master 108 of DUT 114 responds with a delay response message carrying the value T4, which is the time at which PTP grand master 108 of time error measurement tool 100 received the delay request message. PTP slave 118 of DUT 114 receives the delay response and calculates the offset or time error between CLK2 and clock CLK1 of PTP grand master 108 of time error measurement tool 100 as follows:

$$Offset = ( ( T 2 - T 1 ) - ( T 4 - T 3 ) ) / 2$$

PTP slave 118 of DUT 114 updates its local clock as follows:

$$CLK 2 = CKL 1 + Offset$$

PTP master 122 of DUT 114 initiates the process of causing PTP slave 112 of time error measurement tool 100 to synchronize its local clock CLK3 with CLK2 by sending a sync message to PTP slave 112 of time error measurement tool 100. PTP slave 118 of time error measurement tool 100 records the time T2 of receipt of the sync message. PTP master 122 of DUT 114 sends a follow up message carrying the value T1 to PTP slave 112 of time error measurement tool 100. The time value T1 is the time at which PTP master 122 of DUT 114 transmits the sync message. At time T3, PTP slave 112 of time error measurement tool 100 sends a delay request message to PTP master 122 of DUT 114. PTP master 122 of DUT 114 responds with a delay response message carrying the value T4, which is the time at which PTP master 122 of DUT 114 received the delay request message. PTP slave 112 of time error measurement tool 100 receives the delay response and calculates the offset or time error between its clock, CLK3, and clock CLK2 of PTP master 122 of DUT 114 as follows:

$$Offset = ( ( T 2 - T 1 ) - ( T 4 - T 3 ) ) / 2$$

PTP slave 112 of time error measurement 100 updates its local clock as follows:

$$CLK 3 = CKL 2 + Offset$$

The offset calculated by PTP slave 112 of time error measurement tool 100 may be used as an instantaneous measure of time error of DUT 114. PTP slave 112 may feed the offset value as a measurement of time error of DUT 114 to ML model 124.

Time error measurement tool 100 may repeat the synchronization process illustrated in FIG. 2 multiple times with different impairments inserted into the timing synchronization traffic at different times and generate time error measurements calculated by PTP slave 112 of time error measurement tool 100. PTP slave 112 may feed the time error measurements to ML model 124. ML model 124 generates and outputs cluster maps of the time error measurements for different time durations, examples of which will be described below.

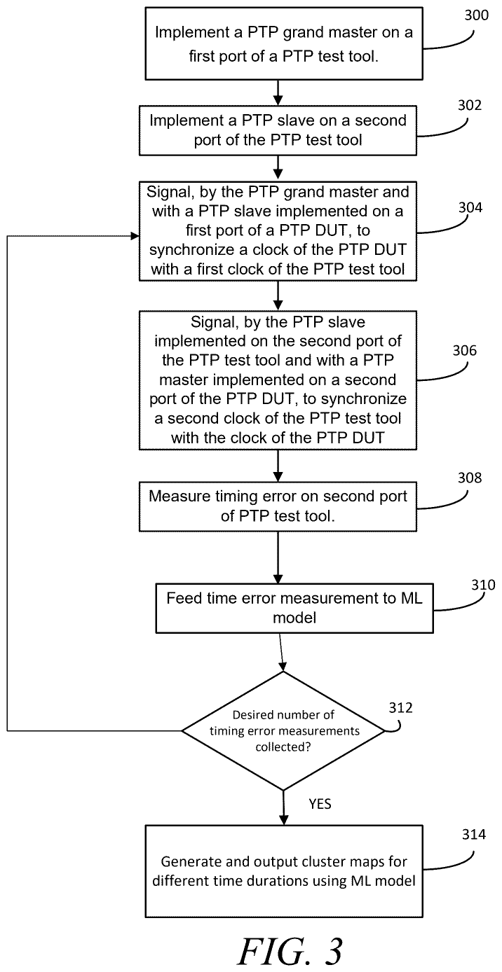

FIG. 3 is a flow chart illustrating an exemplary process for obtaining and processing time error measurements using unsupervised machine learning. Referring to FIG. 3, in step 300, the process includes implementing a PTP grand master on a first port of a time error measurement tool. For example, a time error measurement tool, such as time error measurement tool 100, may implement a PTP grand master on one of its ports.

In step 302, the process further includes implementing a PTP slave on a second port of the time error measurement tool. For example, time error measurement tool 100 may implement PTP slave 112 on one of the ports of time error measurement tool 100.

In step 304, the process further includes signaling, by the PTP grand master and with a PTP slave implemented on a first port of a PTP DUT, to synchronize a clock of the PTP DUT with a first clock of the time error measurement tool. For example, PTP grand master 108 may signal with PTP slave 118 to synchronize CLK2 of DUT 114 with CLK1 of time error measurement tool 100.

In step 306, the process further includes signaling, by the PTP slave implemented on the second port of the time error measurement tool and with a PTP master implemented on a second port of the PTP DUT, to synchronize a second clock of the time error measurement tool with the clock of the PTP DUT. For example, PTP slave 112 may signal with PTP master 122 to synchronize a clock of PTP slave 112 with a clock of PTP master 122

In step 308, the process further includes measuring a time error on the second port of the time error measurement tool. For example, time error measurement tool 100 may calculate a timing offset between the clock of PTP slave 112 and the clock of PTP master 122.

In step 310, the process includes providing the time error measurement to a machine learning model. For example, PTP slave 112 of time error measurement tool 100 may provide the offset measurement to ML model 124

In step 312, the process includes determining whether a desired number of time error measurements have been collected. The desired number of timing error measurements may be determined by the test engineer based on the goals of the particular test. For example, if the test is designed to simulate timing errors caused by power supply instability, then the desired number of timing error measurements may be based on when a configured number of timing synchronization packets with emulated power supply instability impairments are transmitted to the device under test. If the desired number of time error measurements have been collected, control proceeds to step 314 where time error measurement tool 100 generates and outputs cluster maps for different time durations using the ML model.

The subject matter described herein analyzes time errors using unsupervised learning to cluster time errors and identify causes of time errors.

Clustering: Clustering or cluster analysis is an unsupervised machine learning technique, which groups unlabeled data in a dataset. Clustering can be defined as a mechanism of grouping data points into different clusters, consisting of similar data points. The objects with possible similarities are clustered into groups or clusters. Clustering finds similar characteristics in the unlabeled dataset and divides data in the dataset through the presence and absence of the similar characteristics.

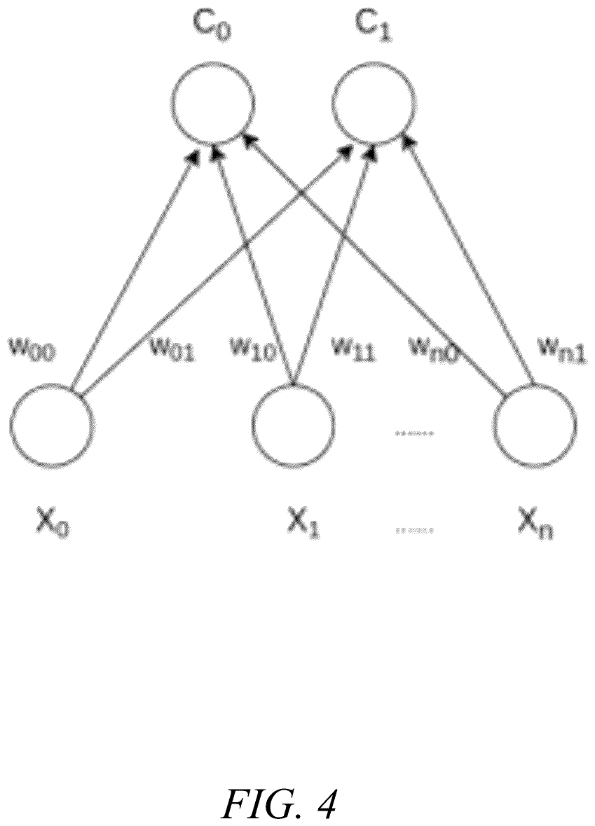

Self-Organizing Maps (SOM): A self-organizing map is a type of artificial neural network which is also inspired by biological models of neural systems. A self-organizing map follows an unsupervised learning approach and trains its network through a competitive learning algorithm. A SOM is used for clustering and mapping (or dimensionality reduction) techniques to map multidimensional data onto lower-dimensional which simplifies complex problems for easy interpretation. FIG. 4 illustrates an example of clustering using self-organizing maps.

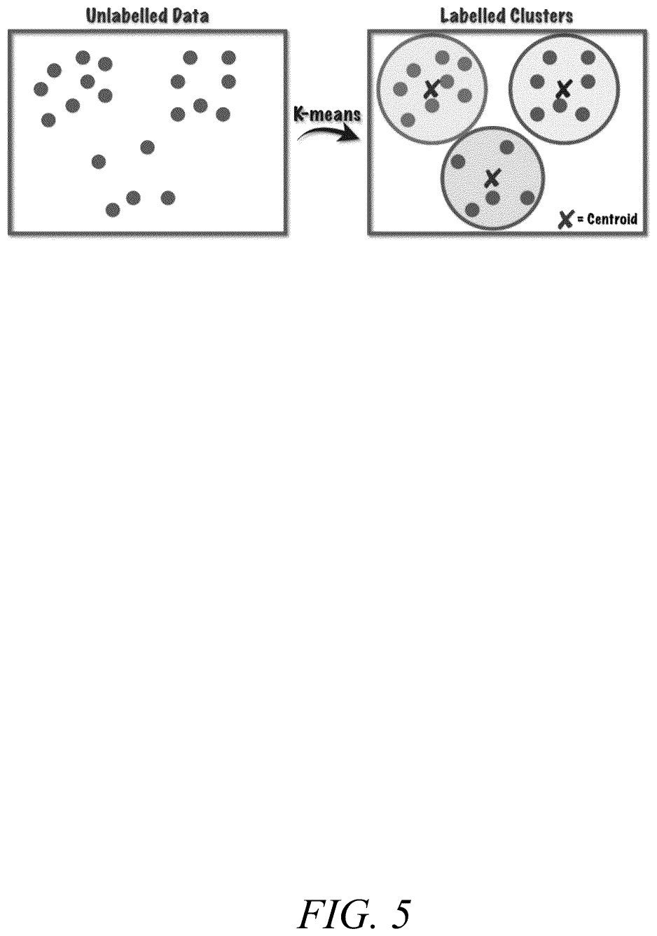

K-Means Algorithm: K-means clustering is another example of an unsupervised learning algorithm, which groups the unlabeled dataset into different clusters. K-means clustering is a centroid-based algorithm, where each cluster is associated with a centroid. The main aim of this algorithm is to minimize the sum of distances between the data point and their corresponding clusters. FIG. 5 illustrates and example of clustering using k-means clustering.

### Problem Definition

One goal of the subject matter described herein is to analyze the nature of the time errors across different sets of samples. The main idea is to find similarities among different time series such that those can be paired in same cluster. Clustering time error data facilitates the understanding and analysis of the time error data. Using clustering, a huge set of data can be represented in a more readable format to analyze the types of errors encountered and to recognize the trends. Clustering can also be used to find the anomalies among time series of time error measurements. This data in combination with other insights will be helpful to determine the root cause of time errors being introduced into the network.

### Solution

Clustering algorithms treat a feature vector as a point in an N-dimensional feature space. Feature vectors from a similar class of data then form a cluster in the feature space. The clustering performed by ML model 124 offers a set of benefits, including the fact that the model can learn without supervision. No supervision or labeling on the data is required. The proposed solution is flexible in that it can be used with time error datasets of different sizes. The clustering described herein has a reduced cost over conventional time error analysis because no supervision or human intervention is required to cluster the time error data. The solution can be customized based on the type of input data. For example, other clustering algorithms like DBSCAN, Gaussian Mixture Model etc. can also be incorporated if needed to analyze the type of input data.

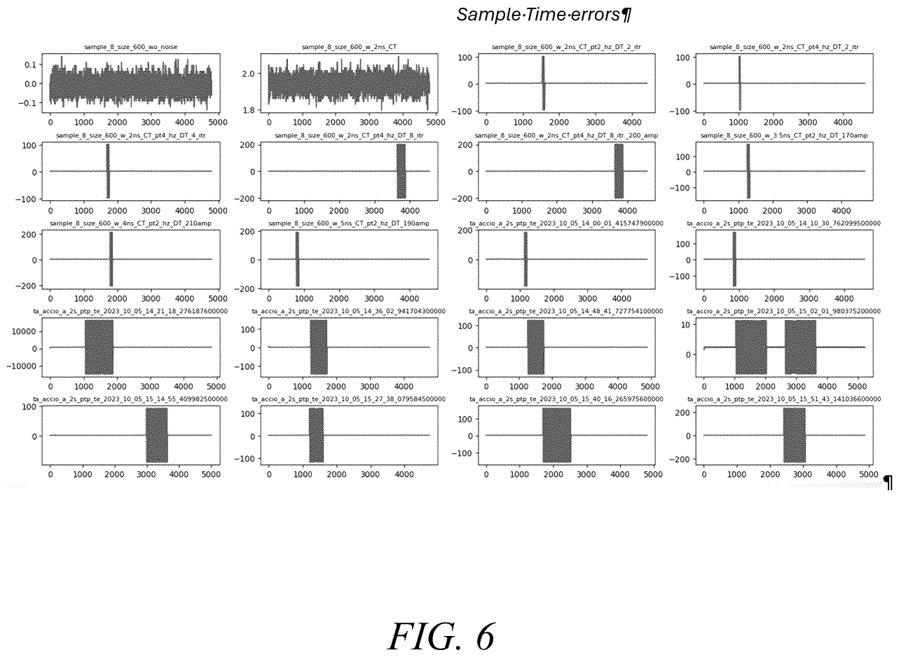

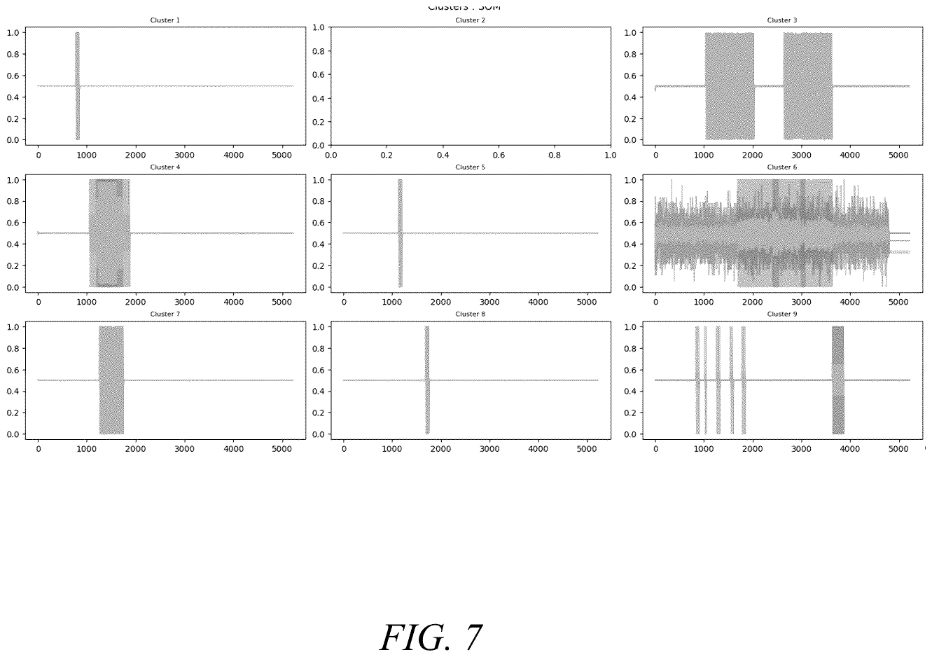

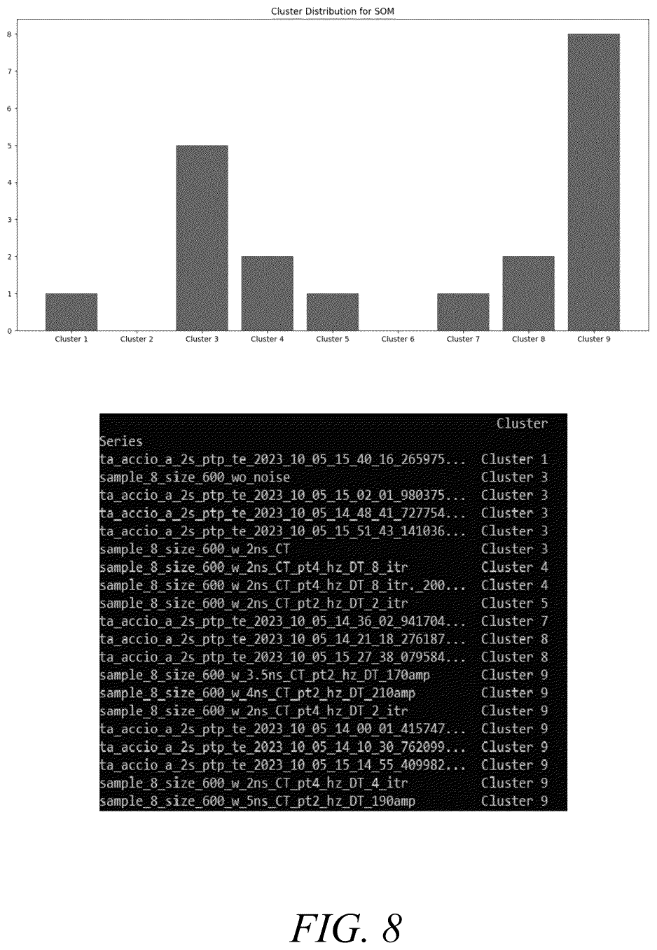

FIG. 6 illustrates an example of some input data series of time error measurements for different time intervals and under different physical conditions that may be provided as input to the ML model. These sample time errors are collected with different impairments that emulate different physical conditions. FIG. 7 illustrates an example of clusters identified by machine learning model 124 when machine learning model 124 is configured to utilize self-organizing maps to generate the clusters. The clusters identified in the top three rows in FIG. 7 illustrated clusters identified using simple averaging (arithmetic mean), and the bottom three rows in FIG. 7 illustrate clusters identified using barycenter averaging, which clusters data features together even when the same features occur at different times. FIG. 8 illustrates a histogram of the clusters of average time error values identified when machine learning model 14 utilizes self-organizing maps. FIG. 8 also illustrates the time series data used to generate the histogram.

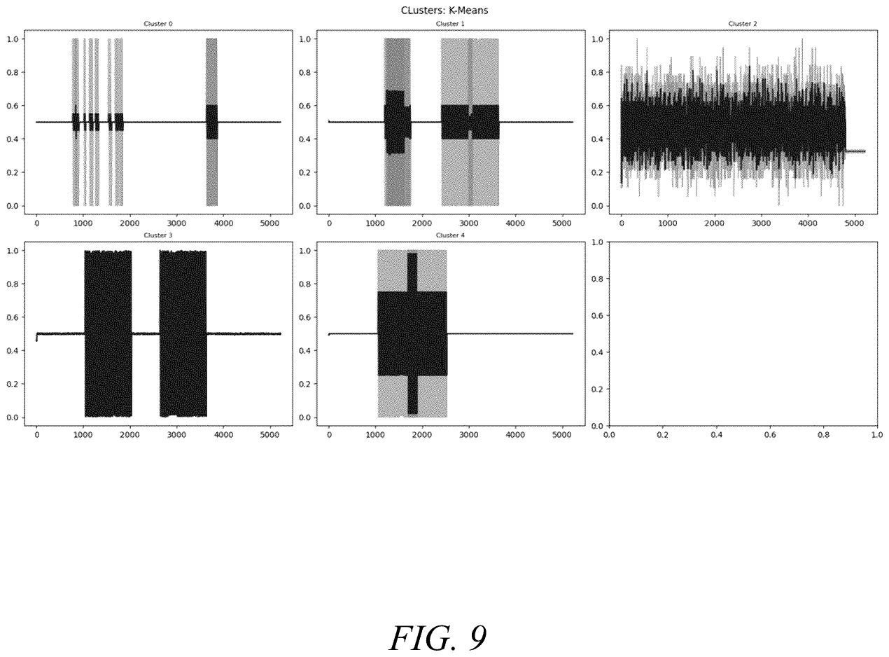

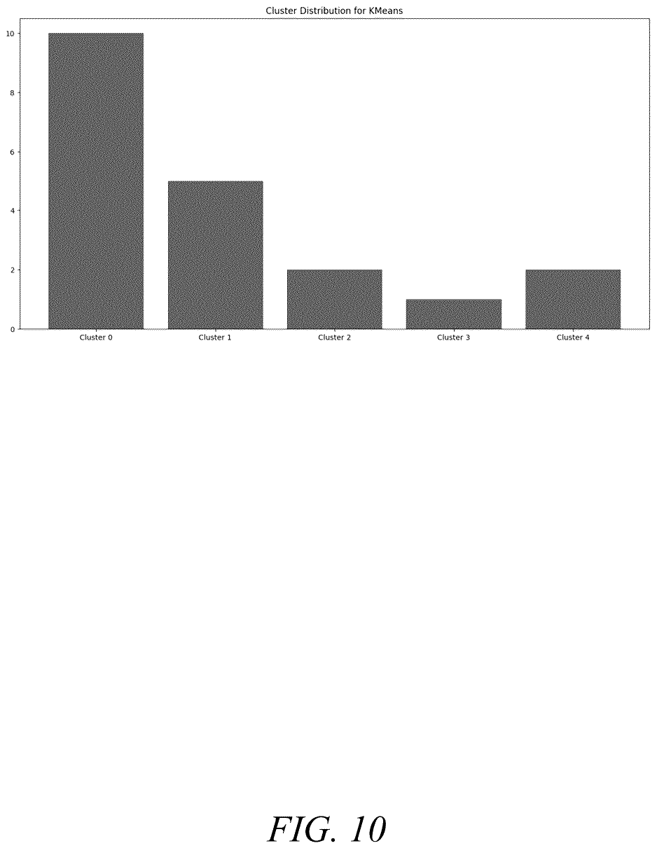

FIG. 9 illustrates clusters of time error values identified by machine learning model 124 for the input time series illustrates in FIG. 6 where machine learning model 124 utilizes k-means clustering to identify the clusters. In FIG. 9, the top 3 rows illustrate clusters of simple average values of the time error measurements, and the bottom 3 rows illustrate clusters of Barycenter average values of the time error measurements. FIG. 10 is a histogram of the clusters of time error measurements identified by machine learning model using k-means clustering.

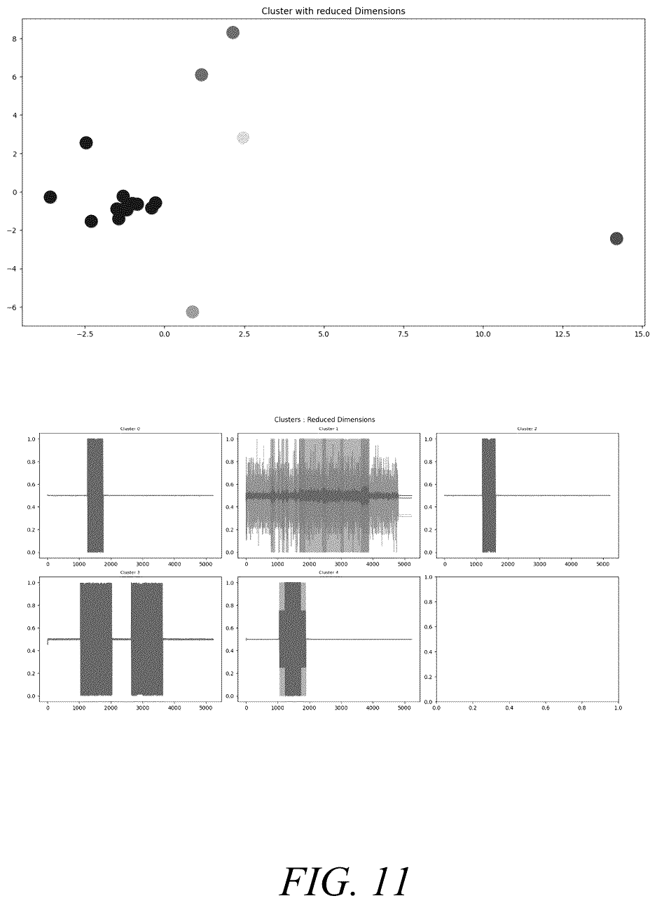

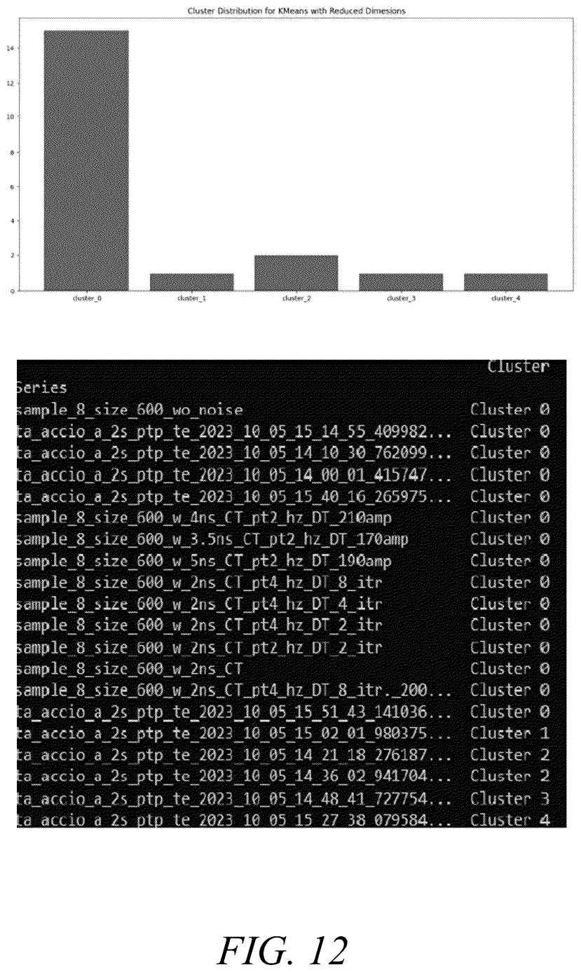

FIG. 11 illustrates clusters with reduced dimensions identified by machine learning model 124 using k-means clustering. FIG. 12 is a histogram of clusters of time error measurements identified using k-means clustering and the time series data used to generate the histograms.

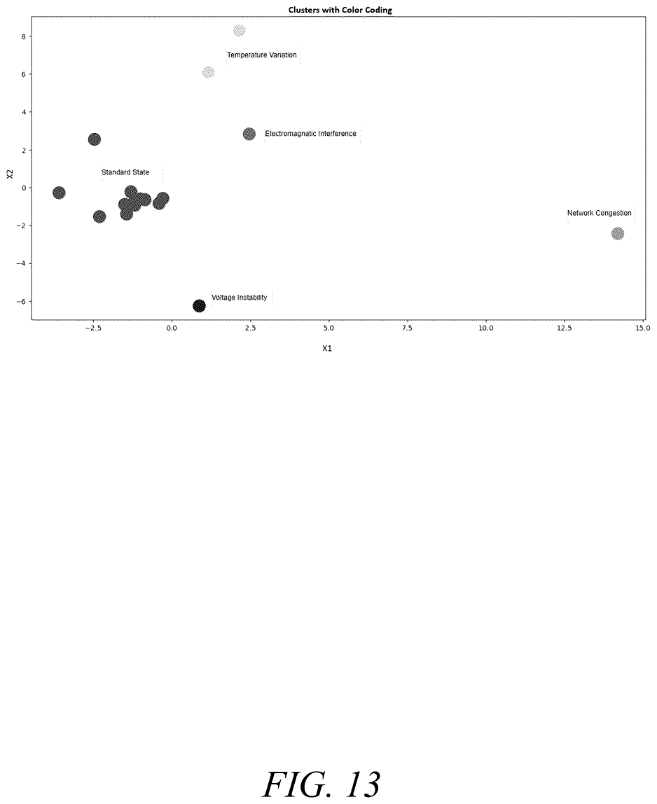

FIG. 13 is a diagram illustrating an example of a dashboard interface for allowing a user to view clusters. In FIG. 13, the identified clusters are labeled with causes of the time errors. In the example illustrated in FIG. 13, the causes of the timing errors include temperature variations, electromagnetic interference, network congestion, and voltage instability. Using the known causes of the simulated time errors, the causes of time errors for clusters identified by ML model 124 for non-simulated time errors can be identified. For example, if the time error clusters identified by ML model 124 are similar to any of the clusters illustrated in FIG. 13, the type of time error may be inferred from the similarity of a cluster to a cluster for which the cause of the time error is known. In addition, once clusters of time errors have been identified and labeled with causes, such clusters and their labels can be used to train an ML model, such as ML model 124 to automatically determine causes of time error from unlabeled data.

The subject matter described herein may be changed without departing from the scope of the subject matter described herein. Furthermore, the foregoing description is for the purpose of illustration only, and not for the purpose of limitation.

What is claimed is:

1. A method for obtaining time error measurements and processing the time error measurements using unsupervised machine learning, the method comprising:
generating, using a time error measurement tool, timing synchronization test traffic and transmitting the timing synchronization test traffic to a device under test;
receiving, by the time error measurement tool, responsive timing synchronization test traffic from the device under test;
generating, by the time error measurement tool, measurements of time error between a clock in the device under test and a reference clock;
feeding the measurements of time error to a machine learning model that utilizes unsupervised learning to cluster the time error measurements; and
receiving, as output from the machine learning model, clusters of the time error measurements for a plurality of different time durations.

2. The method of claim 1 wherein the machine learning model utilizes self-organizing maps to generate the clusters.

3. The method of claim 1 wherein the machine learning model utilizes k-means clustering to generate the clusters.

4. The method of claim 1 wherein generating the time synchronization test traffic includes generating the time synchronization test traffic that includes impairments to simulate different causes of time errors.

5. The method of claim 4 wherein generating the time synchronization test traffic that includes impairments to simulate the different causes of the time errors includes generating the time synchronization test traffic with impairments that simulate power supply instability, network congestion, and temperature variations.

6. The method of claim 5 comprising, identifying, from the clusters, causes of the time errors.

7. The method of claim 6 wherein identifying the causes of the time errors includes correlating the clusters with the impairments included in the time synchronization test traffic.

8. The method of claim 1 comprising providing a dashboard interface for allowing a user to view the clusters.

9. The method of claim 1 wherein the clusters include clusters of arithmetic means of the time error measurements.

10. The method of claim 1 wherein the clusters include barycenter averages of the time error measurements.

11. A system for obtaining time error measurements and processing the time error measurements using unsupervised machine learning, the system comprising:
a time error measurement tool including at least one processor and a memory for generating timing synchronization test traffic, transmitting the timing synchronization test traffic to a device under test, receiving responsive timing synchronization test traffic from the device under test, and generating measurements of time error between a clock in the device under test and a reference clock; and
a machine learning model implemented by the at least one processor for receiving, as inputs, the time error measurements generated by the time error measurement tool and utilizing unsupervised learning to generate, as outputs, clusters of the time error measurements for a plurality of different time durations.

12. The system of claim 11 wherein the machine learning model is configured to utilize self-organizing maps to generate the clusters.

13. The system of claim 11 wherein the machine learning model is configured to utilize k-means clustering to generate the clusters.

14. The system of claim 11 wherein the time synchronization test traffic includes impairments to simulate different causes of time errors.

15. The system of claim 14 wherein the impairments simulate power supply instability, network congestion, and temperature variations.

16. The system of claim 15 comprising a cluster analysis module for identifying, from the clusters, causes of the time errors.

17. The system of claim 11 comprising a dashboard interface for allowing a user to view the clusters.

18. The system of claim 11 wherein the machine learning model is configured to output clusters of arithmetic means of the time errors.

19. The system of claim 11 wherein the machine learning model is configured to output barycenter averages of the time error measurements.

20. A non-transitory computer readable medium having stored thereon executable instructions that when executed by a processor of a computer control the computer to perform steps comprising:
generating, using a time error measurement tool, timing synchronization test traffic and transmitting the timing synchronization test traffic to a device under test;
receiving, by the time error measurement tool, responsive timing synchronization test traffic from the device under test;
generating, by the time error measurement tool, measurements of time error between a clock in the device under test and a reference clock;
feeding the measurements of time error to a machine learning model that utilizes unsupervised learning to cluster the time error measurements; and
receiving, as output from the machine learning model, clusters of the time error measurements for a plurality of different time durations.
